(19) United States
(12) Patent Application Publication
(10) Pub. No.: US 2008/0068803 A1
(43) Pub. Date: Mar. 20, 2008

(54) Heat dissipating device holder structure with a thin film thermal conducting medium coating

(76) Inventor: Shyh-Ming Chen, Taipei Hsien (TW)

Correspondence Address: Shyh-Ming Chen, 235 Chung-Ho, Box 8-24, Taipei, omitted

(21) Appl. No.: 11/522,807

(22) Filed: Sep. 18, 2006

(51) Int. Cl. H05K 7/20

(52) U.S. Cl. 361/705; 361/704; 361/708

(57) ABSTRACT

In a heat dissipating device holder structure with a thin film thermal conducting medium coating, at least two thermal conducting medium coating blocks are set on attaching surfaces of a heat dissipating device holder and a processor, and a gap is disposed between the coating blocks, such that when the heat dissipating device holder is attached to the processor, the compressing force of the heat dissipating device holder and the processor exerted onto the thermal conducting medium coating blocks can be spread to fill the spread thermal conducting medium into a short distance of the gap, so as to achieve the best thin film coating for the thermal conducting medium and effectively lower thermal resistance and attach the heat dissipating apparatus holder tightly with the processor for the best heat dissipation effect.

### BACKGROUND OF THE INVENTION

1. Field of the Invention

The present invention relates to a heat dissipating device holder structure with a thin film thermal conducting medium coating, and more particularly to a heat dissipating device holder structure that attaches at least two thermal conducting medium coating blocks onto an attaching surface of a heat dissipating device holder to form the best thin film that is coated on a heat generating electronic component such as a processor or a chipset, and the thermal conducting medium coating blocks are attached tightly onto the attaching surface to effectively lower the thermal resistance and enhance the heat dissipation effect.

2. Description of the Related Art

Regardless of a high-speed computing processor or a high-end graphic processing chipset, the heat produced by such components become increasingly higher as the clock gets faster and faster. The commonest heat dissipation method adopts a heat dissipating device composed of a heat sink, a heat pipe, a fins or a fan, and the heat dissipating device is installed adjacent to the heat source (and hereinafter referred to as a processor for a representative heat generating source), and uses the principle of thermal conduction to transfer the heat, so as to prevent breakdowns of the high-end computing components in a sudden heat pulse and prevent heat from being accumulated in the system that will increase the system temperature and lower the overall system performance or reduce the reliability or life expectancy of the electronic components.

In general, the connection between the heat dissipating device and the processor cannot be achieved simply by connecting two planes, but it is necessary to coat a thermal conducting medium between the two planes. The thermal conducting medium usually adopts a thermal grease to lower the contact thermal resistance and provide a close attachment of the two planes. Referring to FIG. 1, a heat dissipating device 1 generally comprises a holder 1 and a plurality of fins 11 erected from a bottom plate 10, and the holder 10 is attached correspondingly with a processor 12 for conducting the heat produced by the processor 12 to the holder 10, and dissipating the heat from the fins 11. The contact plane between the holder 10 and the processor 12 is coated with a layer of thermal conducting medium 20. In the traditional attaching process of the heat dissipating device holder 10 and the processor 12, the thermal conducting medium 20 is usually compressed and squeezed out from the connecting surface. Furthermore, the connecting force applied on the heat dissipating device holder 10 and the processor 12 is limited since the heat dissipating device holder 10 is fixed onto the processor 12, and thus an excessively large force applied onto the heat dissipating device holder 10 may damage the processor 12. If the applied force is too large or too small, then the thickness of the thermal conducting medium 20 between the heat dissipating device holder 10 and the processor 12 will not be even, or it may be greater than or smaller than the attaching surface between the two. The heat conduction between the heat dissipating device holder 10 and the processor 12 will be poor (as the thermal conducting medium 20 should be as thin as possible to lower the thermal resistance and avoid adverse effects on the heat conduction). More specifically, the processor 12 may be damaged and the thermal conducting medium 20 may be squeezed out from the attaching surface incurring a waste, if the force applied on the thermal conducting medium 20 is too large. Furthermore, the thermal conducting medium 20 is relatively expensive. If the force applied on the thermal conducting medium 20 is too small, the thermal conducting medium 20 in form a polymer paste will have the properties of poor viscosity and mobility, such that when the thermal conducting medium 20 is compressed, the internal stress cannot effectively spread the thermal conducting medium 20 to form a thin film coating. The excessively thick thermal conducting medium 20 will affect the heat conduction effect, or even produce a gap or result in a poor contact that will lower the heat dissipation efficiency.

In view of the description above, the coating of thermal conducting medium 20 is intended for assisting and enhancing the thermal conduction performance between the processor 12 and the heat dissipating device holder 10, but the properties of the material of the thermal conducting medium 20 and the connecting stress between the heat dissipating device holder 10 and the processor 12 as well as a user's negligence on compressing and damaging the processor 12 may result in an excessively thin or thick layer of thermal conducting medium 20 between the heat dissipating device holder 10 and the processor 12. An uneven or excessively thick coating of thermal conducting medium 20 cannot improve the heat conduction effect; on the contrary, it may even lower the heat conduction effect. Since the thermal conducting medium 20 is intended for providing a heat dissipating medium for the heat conduction between the processor 12 and the heat dissipating device holder 10, therefore providing the thinnest possible and evenly distributed thin film of the thermal conducting medium 20 to lower the coating thickness can improve the overall heat dissipation performance.

### SUMMARY OF THE INVENTION

The primary objective of the present invention is to provide a heat dissipating device holder structure with a thin film thermal conducting medium coating that can effectively reduce the thermal conducting medium coating thickness of a heat sink holder and provide the best thin film coating, such that when a processor is attached, its thermal resistance can be lowered and its heat dissipation effect can be enhanced.

The secondary objective of the present invention is to provide a heat dissipating device holder structure with a thin film thermal conducting medium coating, wherein an even compressing force will be exerted onto a heat sink holder and a processor to distribute an internal stress for resisting the connection with the thermal conducting medium, when the thermal conducting medium coating blocks are attached onto the heat dissipating device holder and the processor, so as to achieve the best thin film attachment. In addition to the effect of effectively lowering the thermal resistance, the invention also reduces the consumption of thermal conducting medium.

A further objective of the present invention is to provide a heat dissipating device holder structure with a thin film thermal conducting medium coating, wherein the thermal conducting medium coating block can be attached onto an area corresponding to the holder and the processor selectively in a grid form, a geometric matrix layout, or an irregular area to fit the thermal attaching surfaces of different models of the heat generating electronic components such as processors and their heat dissipation requirements and provide a more convenient use.

By implementing the aforementioned solution, the present invention can reduce the thermal conducting medium coating thickness of a heat dissipating device and achieve the best thin film coating, such that when a processor is attached, the thermal resistance can be lowered and the heat dissipation effect can be achieved effectively, so as to overcome the shortcomings of having an uneven or excessively thick thermal conducting medium coating between the heat dissipating device holder and the processor of a prior art. Further, the thermal conducting medium coating blocks of the invention are compressed by the holder and the processor and filled into a short distance of the gap to form a thin coating attachment, and thus further reducing the consumption of the thermal conducting medium and lowering the cost. The thermal conducting medium coating blocks are laid on attaching surfaces of the holder by using a silk screen printing method, so as to achieve a more precise, accurate and good connection with the processor.

### BRIEF DESCRIPTION OF THE DRAWINGS

FIG. 1 is a schematic view of combining a heat dissipating device with a processor in accordance with a prior art;

FIG. 2 is a schematic view of combining a compressed thermal conducting medium holder with a processor in accordance with a prior art;

FIG. 3 is a planar view of a basic type of a heat dissipating device that installs thermal conducting medium coating blocks onto the attaching surfaces of a holder and a processor in accordance with a first preferred embodiment of the present invention;

FIG. 4 is a planar view of thermal conducting medium coating blocks installed onto the attaching surfaces of a holder and a processor in accordance with a second preferred embodiment of the present invention;

FIG. 5 is a perspective view of thermal conducting medium coating blocks installed onto the attaching surfaces of a holder and a processor in accordance with a second preferred embodiment of the present invention;

FIG. 6 is a schematic view of compressing thermal conducting medium coating blocks onto a holder and a processor and filling the medium into a short distance of the gap to form a thin film coating in accordance with a second preferred embodiment of the present invention;

FIG. 7 is a schematic view of setting thermal conducting medium coating blocks in a geometric pattern onto the attaching surfaces of a holder and a heat dissipating device in accordance with a third preferred embodiment of the present invention; and

FIG. 8 is a schematic view of setting thermal conducting medium coating blocks in an irregular pattern onto the attaching surfaces of a holder and a heat dissipating device in accordance with a fourth preferred embodiment of the present invention.

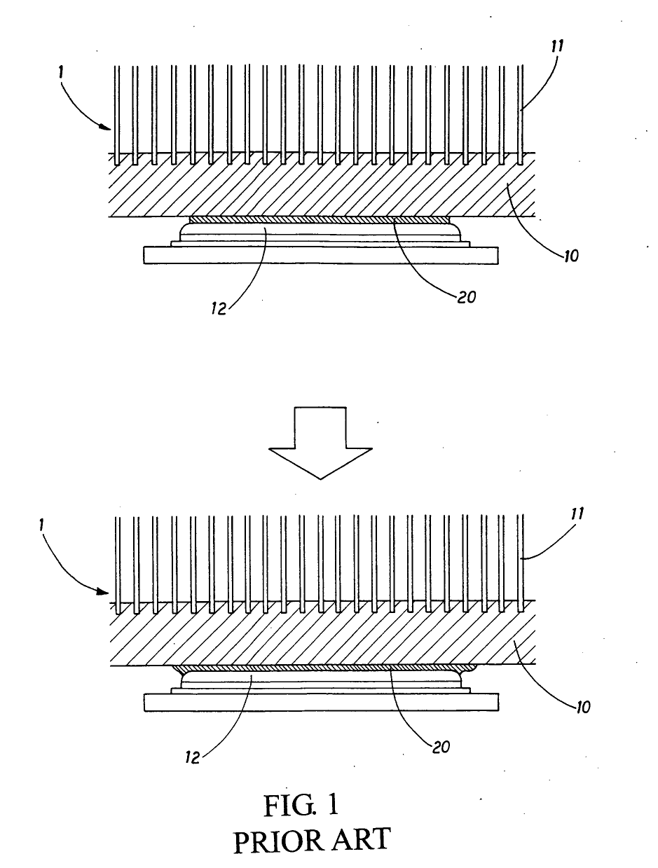

### DETAILED DESCRIPTION OF THE PREFERRED EMBODIMENTS

The above and other objects, features and advantages of the present invention will become apparent from the following detailed description taken with the accompanying drawing.

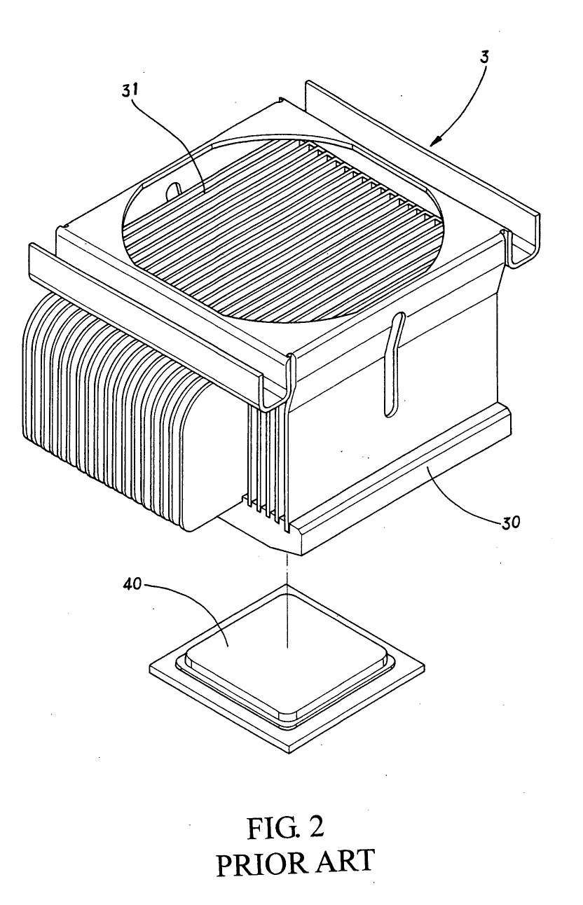

Referring to FIG. 2, a heat dissipating device 3 comprises a holder 30 and a plurality of fins 31 erected from an upper surface of the holder 30, and processor 40 disposed under the holder 30 of the heat dissipating device 3, and the processor 40 could be a central processing unit (CPU), a graphic processing unit (GPU) or any other chipset that will generate a great deal of heat during their operation.

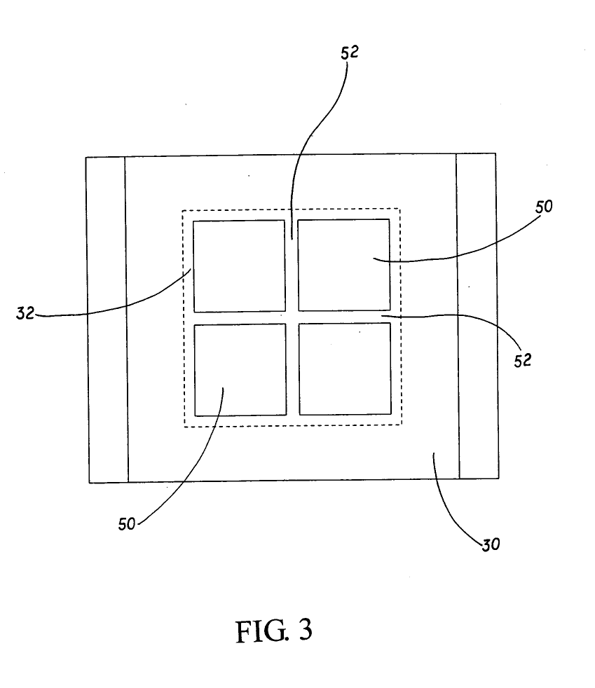

Referring to FIG. 3 for a first preferred embodiment of the present invention, a basic type of a heat dissipating hold structure is illustrated. A plurality of thermal conducting medium coating blocks 50 are disposed on a lower surface of the holder 30, and its related layout is set, wherein at least two thermal conducting medium coating blocks 50 are disposed on the corresponding attaching surfaces of a holder 30 and a processor 40. In FIG. 3, four coating blocks 50 are used for the illustration, but the invention is not limited to such arrangement in actual practices. The coating block 50 is preferably made of a good thermal conducting material such as a thermal conducting glue, a thermal grease (or a heat-conducting paste) or an epoxy by a silk screen printing method and laid on an attaching area 32 corresponding to the holder 30 and the processor 40, and the coating blocks 50 are separated from each other such that a predetermined gap 52 is disposed between two adjacent coating blocks 50, and the gap 52 is defined according to the type of the thermal conducting medium such as a thermal conducting glue, a thermal grease (or a heat-conducting paste) or an epoxy, as well as the difference of viscosity and mobility. Of course, factors including the compressing force for attaching the holder 30 with the processor 40 and even the working temperature for the connection are taken into consideration for determining or changing the parameters of the gap 52. In other words, the gap 52 is preferably adjusted flexibly by the foregoing parameters, so that when the holder 30 and the processor 40 are attached and compressed, the compressed thermal conducting medium coating blocks 50 is spread to fill the thermal conducting medium into at a short distance of the gap 52 to provide the thinnest possible film and completely fill the predetermined attaching area 32 to form a thin film coating.

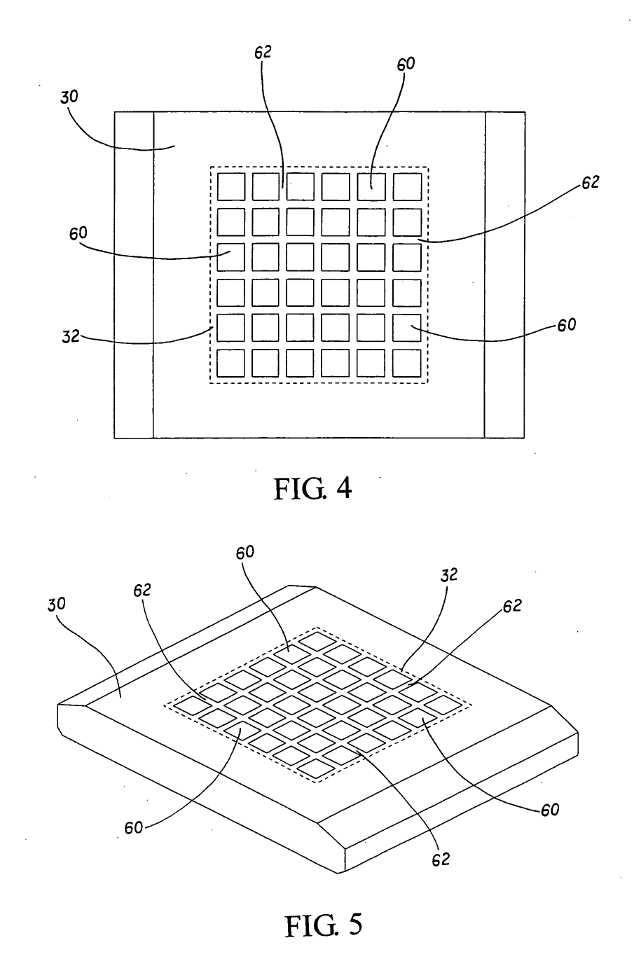

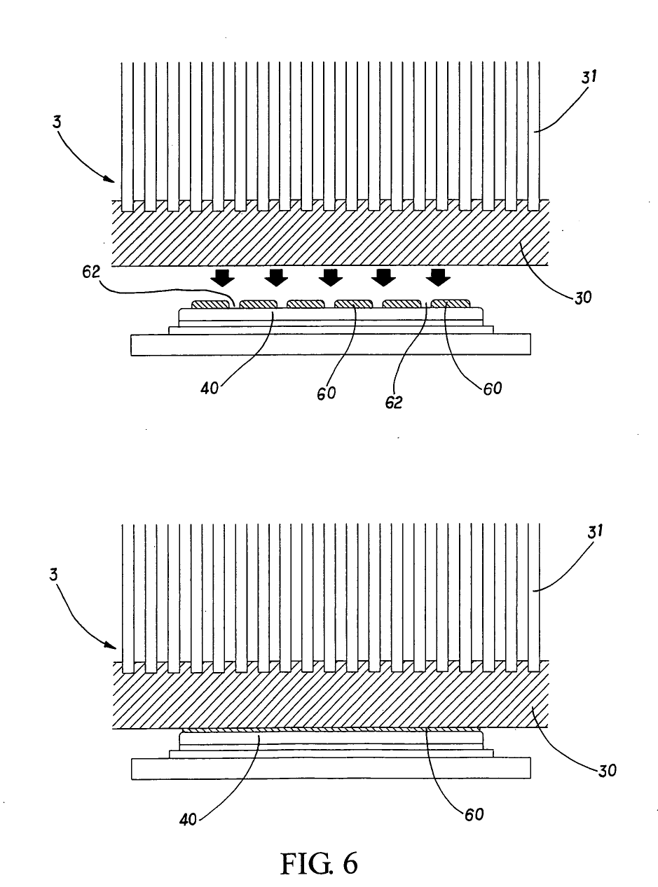

Referring to FIGS. 4 and 5 for a second preferred embodiment of the present invention, the second preferred embodiment is roughly the same as the first preferred embodiment, and the major difference resides on that a plurality of thermal conducting medium coating blocks 60 are disposed in a matrix pattern (which is a 6×6 matrix as shown in the FIGS. 4 and 5) on the attaching areas 32 at the lower end of the holder 30 of the heat dissipating device 3, and a gap 62 exists between the coating blocks 60, such that when the holder 30 is attached to the processor 40, the compressed heat dissipating medium coating blocks 60 are spread (as shown in FIG. 6) to fill the spread thermal conducting medium into a short distance of the gap 62 to form a thin film coating.

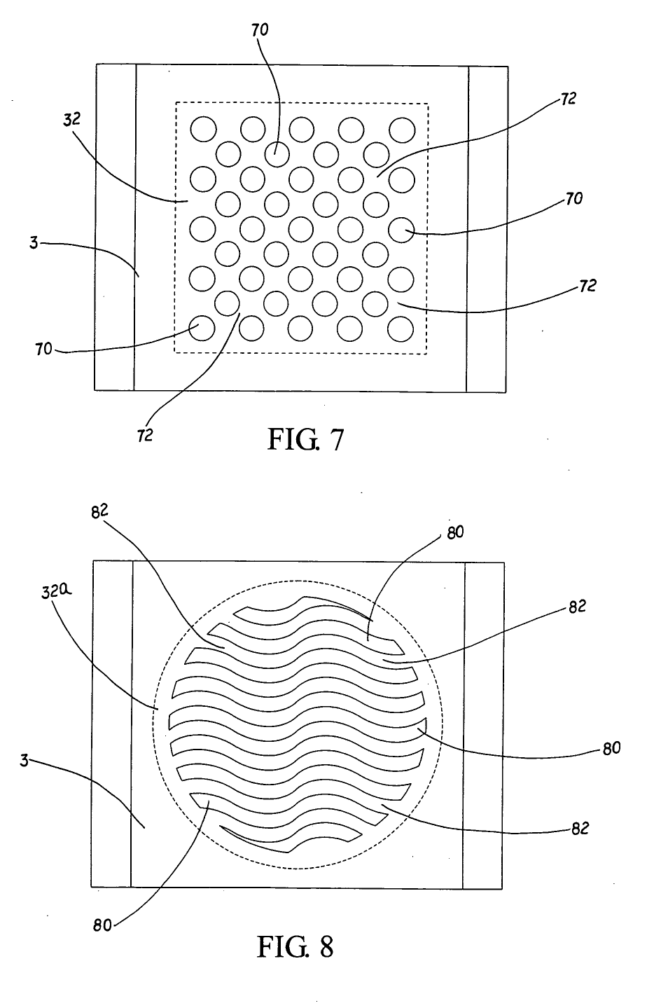

Further, the thermal conducting medium coating blocks 50, 60 are created by using a silk screen printing method, but the invention is not limited to such arrangement, and a traditional coating technology or a traditional transfer printing method can be used for the practical applications of creating the thermal conducting medium coating blocks 50, 60 on the lower surface of the holder 30. As we know, the thermal conducting medium coating blocks 50, 60 can be created in a geometric pattern of coating areas 50, 60, and the coating blocks 70 are in the shape of circular dots as illustrated in a third preferred embodiment of the present invention and shown in FIG. 7 in addition to those illustrated in the first and second preferred embodiments, geometric pattern. The coating blocks 70 are arranged alternately, or in a matrix layout (as shown in FIGS. 4 and 5), and a gap 72 is disposed between the coating blocks 70, and the holder 30 is attached correspondingly with the processor 40 to compress the thermal conducting medium coating blocks 70 to spread, and the spread thermal conducting medium is filled into a short distance of the gap 72, such that the holder 30 is attached tightly with the processor 40 to form a thin film coating.

Referring to FIG. 8 for a fourth preferred embodiment of the present invention, to cope with different processors and their heat dissipation requirements, the holder 30 of the heat dissipating device 3 corresponds to the attaching area 32 of the processor 40. Besides the rectangular shape as illustrated in the foregoing preferred embodiments, the present invention also can adopt a circular area surface 32a or any other geometric shape or irregular shape to define the attaching area, and the defined area surface can adopt a grid form or a circular dot form for the thermal conducting medium coating blocks 60, 70, and it also can adopt the coating blocks 80 with a layout of irregular shape as shown in FIG. 8 and disposed on the attaching surface 32 at the bottom of the holder 30. A gap 82 is disposed between the coating blocks 8, and the holder 30 is attached correspondingly with the processor 40 to compress the thermal conducting medium coating blocks 70 to spread, and the spread thermal conducting medium is filled into a short distance of the gap 72, such that the holder 30 is attached tightly with the processor 40 to form a thin film coating.

1. A heat dissipating device holder structure with a thin film thermal conducting medium coating, comprising:
at least two thermal conducting medium coating blocks, attached to attaching surfaces of a heat dissipating device holder and a processor; and
a gap, disposed between said coating blocks, such that said heat dissipating device holder is attached to said processor, and said thermal conducting medium coating blocks are compressed to fill said thermal conducting medium into a short distance of said gap to form a thin film coating.

2. The heat dissipating device holder structure with a thin film thermal conducting medium coating of claim 1, wherein said thermal conducting medium coating blocks are set on corresponding attaching areas of said holder and said processor.

3. The heat dissipating device holder structure with a thin film thermal conducting medium coating of claim 1, wherein said thermal conducting medium coating blocks are laid in a grid pattern onto said attaching surfaces of said heat dissipating device holder and said processor.

4. The heat dissipating device holder structure with a thin film thermal conducting medium coating of claim 1, wherein said thermal conducting medium coating blocks are laid in a matrix pattern onto said attaching surfaces of said heat dissipating device holder and said processor.

5. The heat dissipating device holder structure with a thin film thermal conducting medium coating of claim 1, wherein said thermal conducting medium coating blocks are laid in a geometric pattern onto said attaching surfaces of said heat dissipating device holder and said processor.

6. The heat dissipating device holder structure with a thin film thermal conducting medium coating of claim 1, wherein said thermal conducting medium coating blocks are laid in an irregular pattern onto said attaching surfaces of said heat dissipating device holder and said processor.

7. The heat dissipating device holder structure with a thin film thermal conducting medium coating of claim 1, wherein said thermal conducting medium is one selected from the collection of a thermal conducting glue, a thermal grease (or a heat conducting paste) and an epoxy.

8. The heat dissipating device holder structure with a thin film thermal conducting medium coating of claim 1, wherein said processor is a central processing unit (CPU), a graphic processing unit (GPU) or a chipset.

9. The heat dissipating device holder structure with a thin film thermal conducting medium coating of claim 1, wherein said thermal conducting medium coating blocks set said thermal conducting medium on said attaching surfaces of said heat dissipating device holder and said processor by a silk screen printing method.
